(19) United States
(12) Patent Application Publication
(10) Pub. No.: US 2013/0116952 A1
(43) Pub. Date: May 9, 2013

(54) POWER METERING SYSTEM AND A METHOD OF DISPLAYING READING DERIVED FROM THE SAME

(71) Applicant: Kok Soon Chai, Penang (MY)

(72) Inventor: Kok Soon Chai, Penang (MY)

(21) Appl. No.: 13/809,827

(22) PCT Filed: Mar. 25, 2011
(86) PCT No.: PCT/MY2011/000027

§ 371 Date: Jan. 11, 2013

(30) Foreign Application Priority Data
Jul. 13, 2010 (MY) PI 2010003306

(51) Int. Cl. G01R 21/133; G06F 15/00

(52) U.S. Cl. CPC G01R 21/133; G06F 15/00
USPC 702/61; 702/189

(57) ABSTRACT

A metering apparatus (100) installed to a distribution network of a consumable commodity comprises a plurality of sensors (110) capable of real-time measuring consumption data of the consumable commodity used by a plurality of recipients (120) located in a single building that each sensor (110) is responsible for measuring consumption rate of one recipient (120) of the consumable commodity and the measurement is acquired as analog signal; a processor (130) connected to the plurality of sensors via a signal processing unit (140), which process and convert the analog signal to digital signal, to obtain the measured consumption data for analysis through instructions from one or more software applications; a storage device (150) in communication with the processor for recording information of the analysis and providing the recorded information to the processor upon request; a display unit (160), which is in communication with the storage device (150) and/or the processor (130), shared and accessible by more than one user of the recipients (120) allowing the user to acquire information of the analysis; and an input means (170) receiving input from the user to command the processor (130) to perform task through the one or more software application; wherein the instructions of one or more software applications are used for consumption data recording, signal processing, automated metering, theft detection, demand management or any combination thereof and the common display is able to simultaneously show analysis information and/or reading of the automated metering of at least two recipients. The home users can connect to the processor to view web-based energy consumption data etc. The processor has the software modules to process signals, ID sensor and privacy module to determine “private” and public views.

### FIELD OF INVENTION

The present invention relates to a system for utilities metering which employs a virtual machine to replace the need to use multiple smarts meter or conventional metering devices for buildings having multiple recipients of the utilities. In more specific, the disclosed invention provides a public platform that the public platform not only eliminates the need of physical metering devices and also allows the users of the utilities to access crucial information about the utilities consumption pattern via a single shared telecommunication service.

### BACKGROUND OF THE INVENTION

Many of the power meters today are analog based with product feature limited to measuring and reporting energy consumption of a household or office. The application of analog-based power meters incurs losses and costs due to non-distribution losses such as electricity theft, billing errors and costly labour intensive customer billing. These conventional metering devices for utilities such as electric, energy, gas, water and the like are typically installed for every utilities recipient in a building. The conventional metering devices must be affordable to be acquired and maintained relative to the total revenue that can be generated from the users. Every metering device consists of a current and voltage interface transducer, an analogue to digital converter, digital signal processing and energy computation function, and an optional communication module. In many occasions, there is a compromise of the features and capabilities of the conventional metering devices in order to achieve an affordable unit price. With advance in telecommunication technology, improved metering system equipped with useful features such as automated meter reading, smart grid features, theft detection and the like using radio frequency, wired network line or the like is introduced to enhance billing efficiency and utilities management. For example U.S. Pat. No. 6,751,563 provides an electronic power meter which feeds power quality and revenue metering information to a remote server via a network protocol, while EP1677270 and U.S. Pat. No. 6,657,552 further propose using power line communication (PLC) and wireless connection for transferring the collected measurement from each smart meter to the remote server respectively. Other improvement in a single smart meter includes metering device offered in U.S. Pat. No. 7,596,459 to meter sub-load in multiple electricity consumer lines in a house and theft detection system of U.S. Pat. No. 4,700,188. U.S. Pat. No. 6,049,791 discloses a utility meter which is connected to different utilities in a receipt unit of these utilities and able to display readings of each utilities. Though the abovementioned inventions offer better billing and management efficiency, still such system are not significantly cost effective to find wide spread adaptation. For example, it incurs cost to maintain the network subscription of each metering device for every user in order to allow a remote server to perform automated meter reading.

Further, the network infrastructure as part of the smart grid linking a large number of metering devices could increase network complexity, thus increasing the installation and maintenance costs. Therefore, eliminating number of metering devices in the smart grid shall lead to the reduction of overall cost of purchase, infrastructure, installation and maintenance. The number of metering devices in a smart grid may be reduced by replacing a plurality of metering devices with one network-enabled virtual metering machine. Network-enabled virtual metering machine also enable smart grid services over computer networks such as but not limited to energy demand management, renewable energy distribution and management, remote theft detection and prevention, energy on-demand management, online payment, utilities account viewing and the like.

### SUMMARY OF THE INVENTION

The present invention aims to provide a virtual machine for replacing the use of multiple metering devices in a building for multiple recipients of a consumable commodity in reading and recording the amount of consumed commodity.

Another object of the present invention is to offer a common shared platform for a plurality of users of the commodity to acquire information about consumption pattern and billing info of the commodity through either the localized virtual machine and/or a remote server. In more specific, the disclosed invention employs a network protocol to connect the platform to the virtual machine and/or a remote server which the cost of the connection is shared by the recipients of the commodity sharing the same virtual machine.

Still another object of the present invention is to provide a cost effective commodity billing and management system. Particularly, the system reduces the cost of installation, maintenance and metering for the used commodity as the virtual machine has eliminates the need of installing and maintaining metering device for each receipt unit. Instead, a virtual machine can simultaneously perform meter reading, recording, billing and other functions for multiple receipt units.

At least one of the preceding objects is met, in whole or in part, by the present invention, in which one of the embodiment of the present invention is a metering system (100) or a virtual metering apparatus installed to a distribution network of a consumable commodity for meter reading to a plurality of recipients comprising a plurality of sensors (110) capable of real-time measuring consumption data of the consumable commodity used by a plurality of recipients (120) located in a single building that each sensor (110) is responsible for measuring consumption rate of one recipient (120) of the consumable commodity and the measurement is acquired as analog signal; a processor (130) connected to the plurality of sensors via a signal processing unit (140), which process and convert the analog signal to digital signal, to obtain the measured consumption data for analysis through instructions from one or more software applications; a storage device (150) in communication with the processor for recording information of the analysis and providing the recorded information to the processor upon request; a display unit (160), which is in communication with the storage device (150) and/or the processor (130), shared and accessible by more than one user of the recipients (120) allowing the user to acquire information of the analysis; and an input means (170) receiving input from the user to command the processor (130) to perform task through the one or more software application; wherein the instructions of one or more software applications are used for consumption data recording, signal processing, automated metering, theft detection, demand management or any combination thereof and the common display is able to simultaneously show analysis information and/or reading of the automated metering of at least two recipients.

In another aspect, the disclosed system or virtual metering apparatus comprises a communication module (180) connecting the processor to a remote server (190) through a first wired or wireless communication that the remote server (190) permits the recipient to make online payment and/or obtains the analysis information from the processor (130) for further analysis and storage via the first wired or wireless communication.

In another aspect, the consumable commodity is electricity and the first wired or wireless communication is a single power line communication.

In another aspect, the system or virtual metering apparatus further comprises a multiplexer disposed in between the connection of the processor and the plurality of sensors prior to the signal processing unit that the multiplexer samples measurement of consumption data from each sensor to the processor at a predetermined duration.

Still another aspect, the disclosed system has a sensing means releasing a signal within a predetermined area to detect presence of a subject around the display unit (160), wherein the sensing means prompt the display unit (160) to be turned off in the absence the subject and prompts the display unit to be turned on once sensing presence of the subject in the predetermined area.

Another major embodiment of the present invention is a method of simultaneously presenting multiple meter readings of a consumable commodity for multiple recipients located in a single building through a display unit (160) comprising the steps of measuring consumption data of the consumable commodity of each recipient (120) using a sensor (110) that the sensor (110) measures consumption data without processing the consumption data; gathering each measured consumption data from multiple recipients by a processor (130); wherein each measured consumption data is processed via a signal processing unit (140) before being acquired by the processor; analyzing each measured consumption data of each recipient (120) by the processor (130) through instructions of one or more software applications to provide analysis information for each recipient; recording the analysis information of each recipient (120) in a storage device (150); retrieving analysis information and/or measured consumption data of each recipient from the storage device (150) and/or the processor (130); and displaying the retrieved analysis information and/or measured consumption data of each recipient including the meter reading simultaneously in the display unit (160).

Further the method may comprise the step of turning off the display unit (160) when no input is received by the processor (130) via an input means (170) and turning on the display unit (160) upon receiving input from the input means (170).

### BRIEF DESCRIPTION OF THE DRAWINGS

FIG. 1 shows the schematic flow of conventional metering system in a smart grid;

FIG. 2 is a schematic diagram showing one embodiment of the disclosed invention;

FIG. 3 is another schematic diagram showing installation and connection of various elements of the present invention is an apartment floor with multiple receipt units;

FIG. 4 is a schematic diagram illustrating one embodiment of the disclosed system with privacy policy;

FIG. 5 is an exemplary public view shown on the display emit; and

FIG. 6 is an exemplary private view shown on the display unit.

### DETAILED DESCRIPTION OF THE INVENTION

The most preferred embodiment of the invention is now described with reference to the figures, where like reference numbers indicate identical or functionally similar elements. While specific configurations and arrangements are discussed, it should be understood that this is done for illustrative purposes only. A person skilled in the art will recognize that the other configurations and arrangements can be used without departing from the scope of the invention.

The terms “recipient” and “receipt unit” are used interchangeably throughout this specification referring to single house unit, office unit, factory unit or the like which uses the supplied commodity and is billed by the commodity service provider as a single unit. There may be multiple users or sub-loads in the receipt unit.

The terms “apparatus”, “virtual metering apparatus”, “metering apparatus”, “system”, “metering system” are used interchangeable throughout this specification referring to the different connected, joined or installed hardware and software collectively used for metering the supplied commodity to multiple recipients.

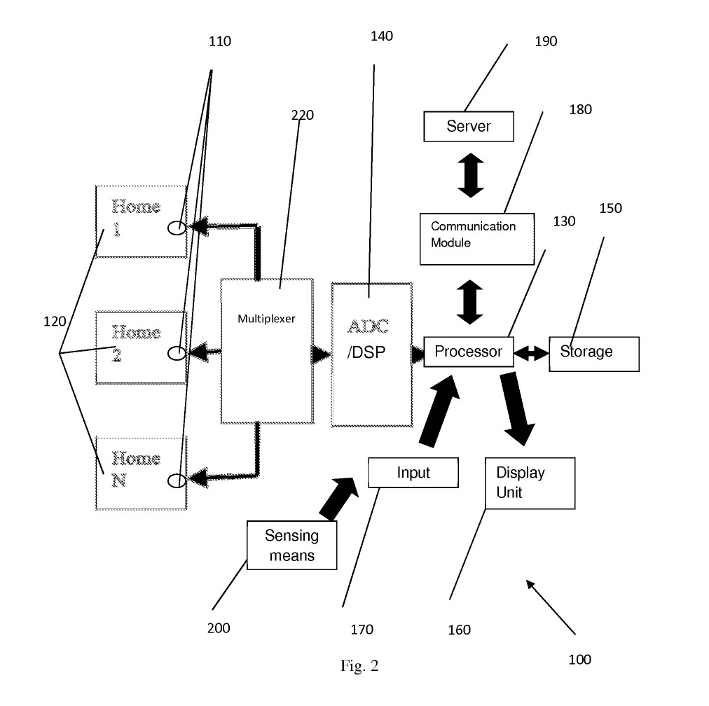

One of the embodiments of the present invention is a metering system (100) or a virtual metering apparatus installed to a distribution network of a consumable commodity for meter reading to a plurality of recipients, as in FIG. 2, comprising a plurality of sensors (110) capable of real-time measuring consumption data of the consumable commodity used by a plurality of recipients (120) located in a single building that each sensor (110) is responsible for measuring consumption rate of one recipient (120) of the consumable commodity and the measurement is acquired as analog signal; a processor (130) connected to the plurality of sensors via a signal processing unit (140), which process and convert the analog signal to digital signal, to obtain the measured consumption data for analysis through instructions from one or more software applications; a storage device (150) in communication with the processor for recording information of the analysis and providing the recorded information to the processor upon request; a display unit (160), which is in communication with the storage device (150) and/or the processor (130), shared and accessible by more than one user of the recipients (120) allowing the user to acquire information of the analysis; and an input means (170) receiving input from the user to command the processor (130) to perform task through the one or more software application; wherein the instructions of one or more software applications are used for consumption data recording, signal processing, automated metering, theft detection, demand management or any combination thereof and the common display is able to simultaneously show analysis information and/or reading of the automated metering of at least two recipients. The commodity in the disclosed invention refers to electricity, gas, or water, though the disclosed system is more preferably used in electricity distributing system.

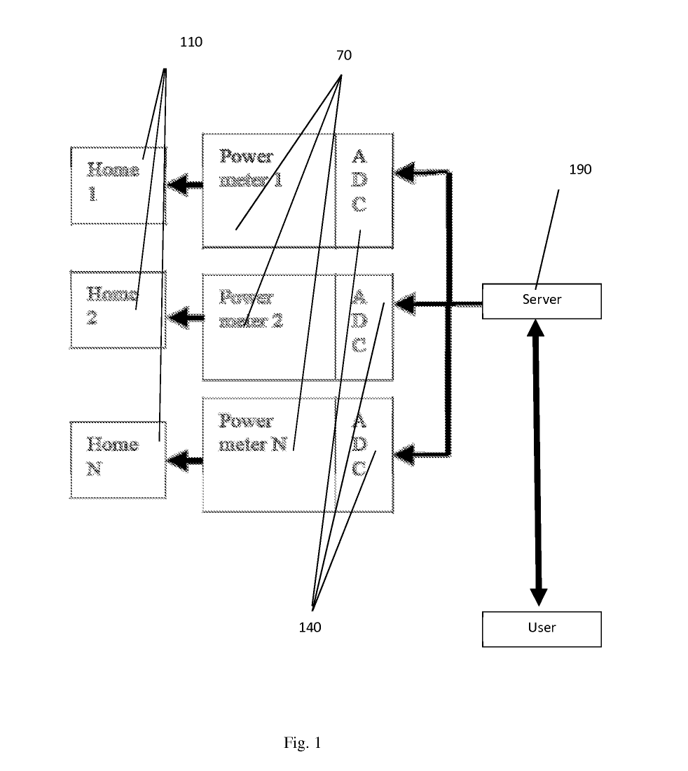

According to the preferred embodiment, the sensor (110) is installed to a point, of the commodity distribution network, which the commodity passes through before being supplied to each receipt unit (120). Thus the volume or amount of the commodity passed through the point can be measured. Preferably, one sensor type can only measure one type of commodity. The sensor (110) in the present invention only measures the real time volume or amount of the commodity without further processing or recording the measured amount. More preferably, in metering and billing consumption of electricity, the sensor (110) can be current and/or voltage transducer. The transducer continuously generates an analog signal that the amplitude of the analog signal is direct proportion to the current and/or voltage passed through. Further, mass flow sensor is employed in the embodiment where the commodity is gas or water. The water or gas flow through the sensor moves a pedal or vane and voltage is generated proportional to the moved distance of the pedal. Thus, the mass flow sensor can measure the volume of gas or water passed by. The amplitude of the measured analog signal is sent to the signal processing unit and processor for further process and use. It is important to be noted that metering, recording, analysis and so on are not conducted at the recipient level. The sensor installed at each receipt unit feeds the measured signal to a signal processing unit that the signal processing unit is shared by multiple recipients and receives the measured analog signal from different sensors of multiple recipients. In contrast, the conventional technologies, as illustrated in FIG. 1, the conventional system has metering devices, such as electric, energy, gas, water meters typically installed for every recipient (120) such as housing units of an apartment, office unit of an office building and the like. Every metering device in the conventional system is costly as it at least includes a current and voltage interface transducer, an analogue to digital converter, digital signal processing and energy computation function, and an optional communication module.

The signal processing unit (140) is preferably an analog to digital converter (ADC) and it is possible to have multiple signal processing unit (140) connected to a single processor (130). The ADC (140) converts the analogue values to digital representations that are then passed to the signal processor such as DSP, processor (130) or micro-controller via a data bus. Preferably, the present invention may have the ADC integrally fabricated or structurally joined to the DSP, micro-controller or the processor as a single unit that the ADC forms part of the DSP, micro-controller or the processor. The data bus may be a SPI, I2C bus, parallel bus, a network cable and the like. The ADC converts analogue signal to digital signal which can be recognized and processed by the processor (130). The converted signal may be subjected to further process at the processor to amplify the signal and/or remove noises. The processor 130 can run of a number of software applications but not limited to data storage, signal processing, automated metering, theft detection, communication module, demand management and the like to perform various smart metering tasks for multiple recipients. To be noted, the instructions of the software are stored in the storage device (150) to be read by the processor (130). It should be appreciated that the software applications can include other smart grid applications that are not stated in the present invention. The total energy consumption and the like are computed in the form of digital representation and stored on storage device. It is possible to have energy measurement chip such as ADE7761B from Analog Devices, 71M6541D from Teridian and the like implemented as system-on-chip (SOC). The SOC may comprise ADC, signal processing and energy computing features in the same chip. The SOC probably stores energy consumption data until it is retrieved by the microprocessor 140.

One of the preferred embodiment of the disclosed system may not have the processor (130) continuously received measurement from all the connected sensors (110). Preferably, the disclosed system contains a flexible algorithm and electronics circuit to sample measurement of the commodity from the certain number of sensors (110) installed at the recipients (120) for the processor to compute the amount of consumed commodity. FIG. 2 shows sampling of current and voltage value using one or more multiplexer in an electricity distribution network. In the figure, the input power transmission line of each recipient (120) has one current and one voltage sensor for energy consumption measurement. The processor (130) has the flexibility to choose which sensor (110) to read by selecting one input of the multiplexer (220). For example, if there was N number of recipient (120) to be read, the processor (130) samples only the N number of current and voltage sensors using a time division method. However, the there may be more than one multiplexer to process multiple number of current and voltage sensors. For example, certain energy measurement chips can measure 2 or 4 housing units simultaneously. Therefore, there may more than one multiplexer and ADC for tens of housing units. The processor (130) computes the consumed amount of these recipients using the sampled current and voltage values. In more specific, the disclosed system comprises a multiplexer disposed in between the connection of the processor (130) and the plurality of sensors (110) prior to the signal processing unit (140) that the multiplexer (220) samples measurement of consumption data from each sensor to the processor (130) at a predetermined duration. The sampling rate may be in the scale of micro second.

Pursuant to another embodiment, the disclosed system may have a communication module (180) connecting the processor to a remote server (190) through a first wired or wireless communication that the remote server (190) permits the recipient to make online payment and/or obtains the analysis information from the processor (130) for further analysis and storage via the first wired or wireless communication. The recipient can also connect to Internet services hosted by the processor. The communication module mentioned includes both hardware and software to establish the connection. The hardware part refers to both wired and/or wireless network communication device capable of using any known network protocols such as 3G, WiMAX, power line communication, LAN line and the like, while the software part is instructions installed at the storage device (150) to be carried out by the processor (130) to establish the connection. Further, an internet access service, the first wired or wireless communication, has to be subscribed in this embodiment to permit establishment of the connection. The disclosed system (100) only requires single subscription for internet access to deliver the commodity consumption information to the remote server (190) for backup storage and further analysis. Costs for subscribing the internet access service in the disclosed system (100) can either borne by the recipients (120) or the commodity provider. The fees is equally divided among the recipients (120), in the former condition, which has greatly relieved the burden of the recipients (120) compared to conventional smart meters where each recipient needs a standalone internet access service for meter reading. In the latter, the cost for the commodity provider to institute and maintain the smart grid has significant reduced as well. The communication module (180) allows the server (190) communicate remotely to the processor (190) for automated billing, theft detection, commodity demand management and so on. In the embodiment where the consumable commodity is electricity, preferably the first wired or wireless communication employed is power line communication. In another preferred embodiment, the user may access information such as billing history, consumption pattern, consumption history and so on from the copy stored at the server (190) and made online payment at the server (190) through the shared first wired or wireless communication. Still another embodiment, the information can be acquired from the storage device (150) without making a request to the server (190). More preferably, the online payment can only be done at the server (190) which is equipped with better network security. The disclosed system also permits the commodity provider to make announcement using the display unit (160). More particularly, the announcement is sent through the server (190) to the processor (130) for further display on the display unit (160). Firmware or software to be run in the processor (130) can be updated by the commodity provider through the server-processor connection.

Further embodiment of the disclosed system (100) may require the user to be verified before acquiring any other information, particularly conducting online payment, besides latest meter reading. Thus, in this embodiment, the system is integrated with an user verification module that it may employs user password, face recognition, national identity card, credit card and the like to identify and verify users wish to instruct the system to perform various tasks related to the commodity demand and supply. More preferably, there are at least two levels of security for accessing the commodity consuming information stored in the storage device (150) and/or the server (190). Through the input means (170) and the display unit (160), normal user may be only allowed to access corresponding individual account while technicians of the commodity provider has the right to access all accounts of all recipients. This is particular important for the commodity provider to maintain and manage the supplied commodity as well as for theft detection. Preferably, the technician can also command the processor (130) to terminate supply of the commodity to a recipient if the payment is overdue.

For detection of commodity theft in the embodiment where the commodity is electricity, Kirchoff's Law is applied in the computing at the processor (130) or server (190). Kirchoff's Law states that the sum of current output is equal to the sum of current input. The same theory applies to voltage. The disclosed system (100) measures the sum of electricity introduced into the recipients and compares it to the sum of the recorded electricity consumed. Any tempering of the power distribution line can be detected with the unbalanced reading of the electricity input and electricity output. For example, the server (190) records the amount of electricity directed to a building and compares it to the consumed electricity recorded by the processor (130) to determine if electricity theft has occurred.

The input means (170) in the present invention refers to tools which allows the user to communicate and give commands to the processor (130) to perform various tasks such as online payment, data acquiring and presentation on billing history, consumption pattern, billing rate and so on. The tools can be, but not limited to, keyboard, mouse, card reader for payment using credit card or account verification using identity card, and the like. Besides, the input means of the present invention may controls the operating modes such as sleep or active mode of the display unit (160) in order to reduce electricity consumption and increase the service life of the display unit (160). In more specific, the display unit (160) is turned off when no input is received from the input means (170) by the processor (130) for a predetermined duration and is turned off upon receiving input from the user via the input means (170).The input means for prompting the display unit (160) to turn on from sleep mode includes at least one sensing means (220). This sensing means emits a signal beam, preferably infra-red light, within a predetermined area around the display unit (160) to detect presence of a subject around the display unit (160), particularly disruption in the signal beam shall generate a signal at the sensing means (220) prompting the display unit (160) to be turned on. Further, any other signal generated from other input means (170) may also shift the display unit (160) to the active mode. For example, tapping the keypad or moving the mouse shall activate the display unit (160) from the sleeping mode.

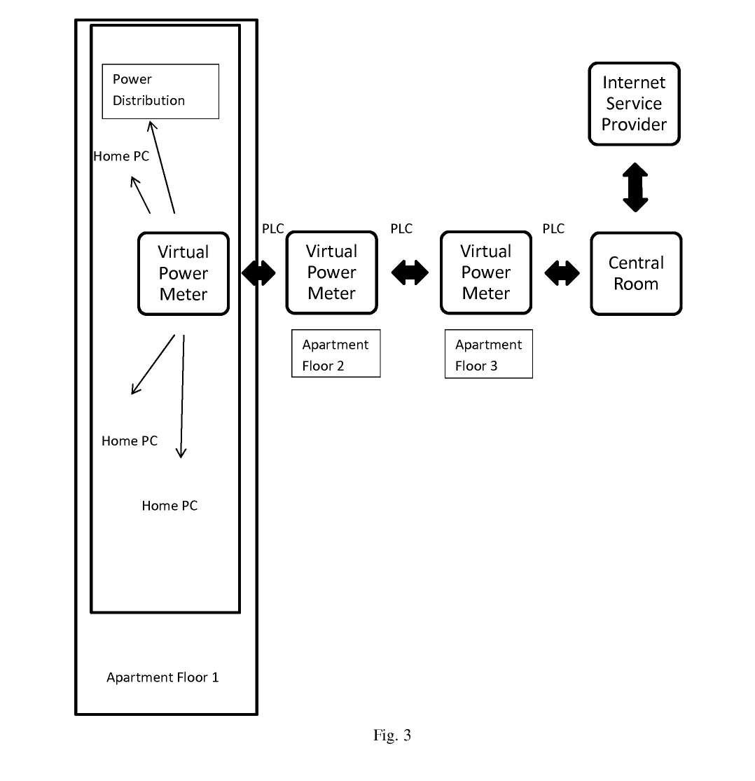

In another preferred embodiment, the display unit (160) in the disclosed system (100) is a flat panel display which is able to simultaneously display multiple meter readings of a commodity of different recipients. More preferably, the flat panel display of the present invention shows virtual representation of the actual electric meters and readings for at least two recipients on the screen, more preferably with label to indicate the identity of the recipient. The flat panel display is preferably positioned at a place in the building where users can easily access to. Such feature is particular useful in area which the billing is not performed automatically via the server or a billing server but rather using manual meter reading via a commodity provider's personnel. In an apartment with multiple floor level, the personnel can easily read the meter and bill accordingly through the readings shown in the display unit, probably at the ground floor, free from nuisance of moving unit from unit of houses to carry out the billing. For example, as in FIG. 3, the energy consumption data of the each housing units or recipient of an apartment are captured, stored and transmitted by disclosed system that the energy consumption data is presented by the virtual electric meters shown on the flat display panel. A touch screen panel may be used in the present invention that the input means (170) and the display unit (160) are integrally fabricated as a single unit.

Apart from using the first communication, the remote server (190) of the disclosed system is accessible through a second wired or wireless communication by the users too. The second wired or wireless communication mentioned herein is any other connection to the server besides the first wired or wireless communication shared by multiple users. Users can use own subscribed internet access service or any other free service provided to establish communication to the server. Via the second wired or wireless communication, the user can access information stored in the server and use any other application such as online payment thereof. However, the information in storage device (150) is not accessible via the second wired or wireless communication.

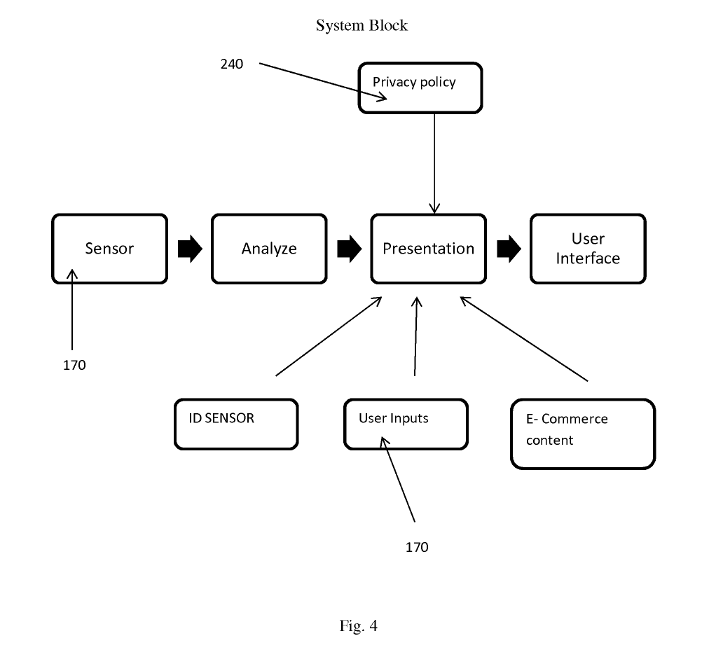

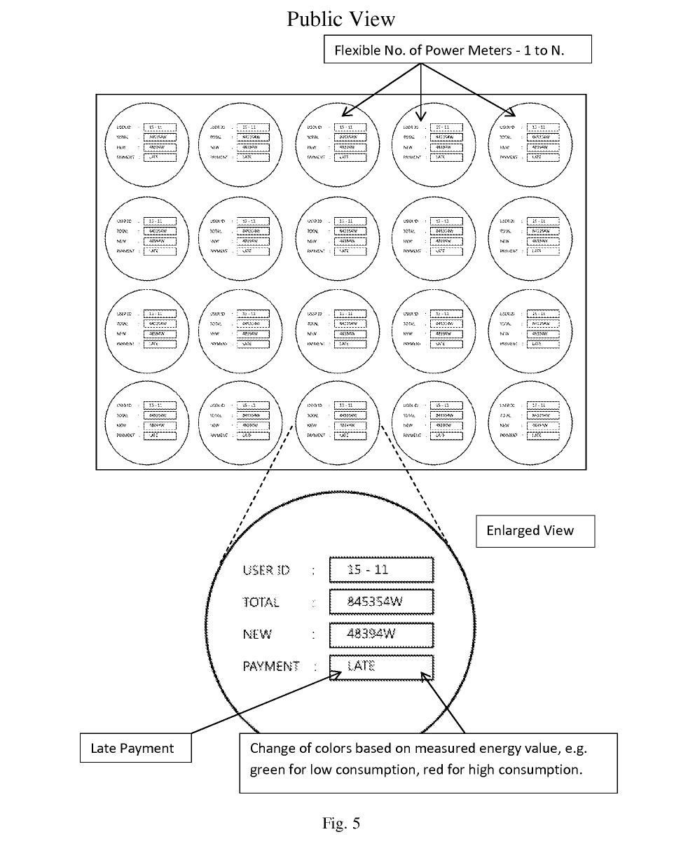

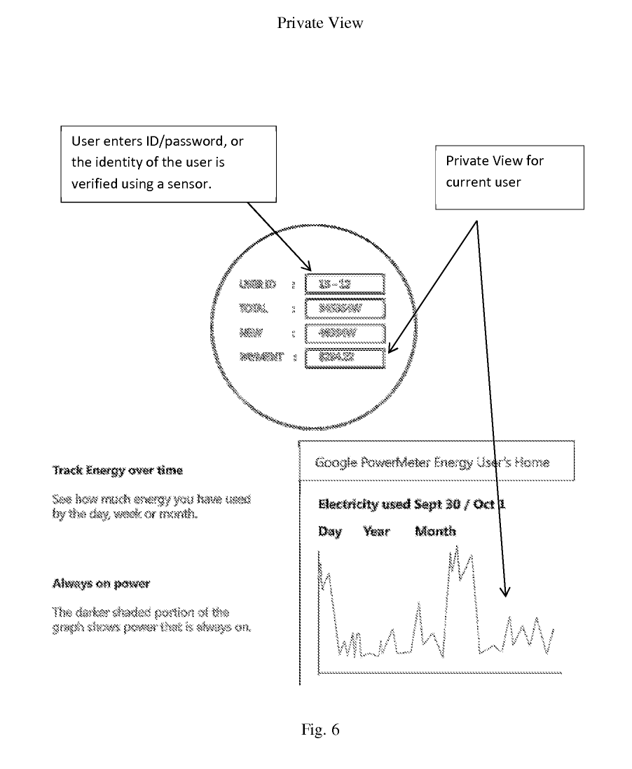

In another aspect, illustrated by FIG. 4, the processor (130) process the input signals and employs a privacy policy (240) to determine the way the display unit (160) present the information. Since the display unit (160) of the disclosed system is preferably located at a public area to promote easy access, the display unit may present the information in at least two different levels namely “public” and “private” interfaces for the users. The processor processes both the privacy policy (240) and inputs from the user to determine the types and amount of information to be display for the “public” and private” views as in the examples shown in FIGS. 5 and 6. Based on the rules in the privacy policy, the display unit (160) can display over usage, late payment and total energy consumption data to the general public.

However, a user ID and password, or any biometrics etc. is needed to verify the true identity of an user is required in order to display the “private” view. User can perform e-payment, check real time or historical consumption data, or check bills in the “private” view. It is important that the display unit (160) may not be a color LCD, any character-based LCD may also be able to display meter reading information for a plurality of users. A text-based LCD can also display “public” and “private” views. More specifically, the privacy policy (240) provides sets of configured criteria followed by the processor (130) for presenting information on the display unit (160).

Another embodiment of the present invention is a method of simultaneously presenting multiple meter readings of a consumable commodity for multiple recipients located in a single building through a display unit (160) which can be applied in the system mentioned above. The method comprises the steps of measuring consumption data of the consumable commodity of each recipient (120) using a sensor (110) that the sensor (110) measures consumption data without processing the consumption data; gathering each measured consumption data from multiple recipients by a processor (130); wherein each measured consumption data is processed via a signal processing unit (140) before being acquired by the processor; analyzing each measured consumption data of each recipient (120) by the processor (130) through instructions of one or more software applications to provide analysis information for each recipient; recording the analysis information of each recipient (120) in a storage device (150); retrieving analysis information and/or measured consumption data of each recipient from the storage device (150) and/or the processor (130); and displaying the retrieved analysis information and/or measured consumption data of each recipient including the meter reading simultaneously in the display unit (160). As above mentioned, the commodity in the disclosed method refers to electricity, gas, or water. Yet, the disclosed method is more preferably applied in electricity supplying service. The sensor (110) has to be located at a point in the commodity distribution network where the commodity passes through before being supplied to each receipt unit (120). Thus the volume or amount of the commodity going beyond the point can be measured. In metering and billing consumption of electricity, the sensor (110) can be current and/or voltage transducer.

Further, the instructions of one or more software applications run by the processor are used for consumption data recording, signal processing, automated metering, theft detection, demand management or any combination thereof.

To avoid electricity wastage and extend service life of the display unit, the disclosed method further comprises the step of turning off the display unit (160) when no input is received by the processor (130) via an input means (170) and turning on the display unit (160) upon receiving input from the input means (170). In more specific, the display unit (160) is turned off when no input is received from the input means (170) by the processor (130) for a predetermined duration and is turned off upon receiving input from the user via the input means (170).The input means for prompting the display unit (160) to turn on from sleep mode includes at least one sensing means (220). This sensing means emits a signal beam, preferably infra-red light, within a predetermined area around the display unit (160) to detect presence of a subject around the display unit (160), particularly disruption in the signal beam shall generate a signal at the sensing means (220) prompting the display unit (160) to be turned on. In one of the embodiments, the display unit (160) in the disclosed system (100) is a flat panel display which is able to simultaneously display multiple meter readings of a commodity of different recipients. More preferably, the energy consumption data is presented by the virtual electric meters shown on the display unit (160). A touch sensitive display panel may be used in the disclosed method that the input means (170) and the display unit (160) are integrally fabricated as a single unit.

Moreover, announcement or message from the commodity provider may be announced through the display unit (160) as well. More specifically, the method may additionally has a step of connecting the processor (130) to a remote server (190) via a communication module and announcing a message received from the server (190) using the display unit (160)

It is to be understood that the present invention may be embodied in other specific forms and is not limited to the sole embodiment described above. However modification and equivalents of the disclosed concepts such as those which readily occur to one skilled in the art are intended to be included within the scope of the claims which are appended thereto.

1. A metering apparatus installed to a distribution network of a consumable commodity for meter reading to a plurality of recipients, comprising:
a plurality of sensors capable of real-time measuring consumption data of the consumable commodity used by the plurality of recipients located in a single building that each sensor is responsible for measuring consumption rate of one recipient of the consumable commodity and the measurement is acquired as analog signal;
a processor connected to the plurality of sensors via a signal processing unit, which process and convert the analog signal to digital signal, to obtain the measured consumption data for analysis through instructions from one or more software applications;
a storage device in communication with the processor for recording information of the analysis and providing the recorded information to the processor upon request; a display unit, which is in communication with the storage device and/or the processor, shared and accessible by more than one user of the recipients allowing the user to acquire information of the analysis; and
an input system receiving input from the user to command the processor to perform task through the one or more software application;
wherein the instructions of one or more software applications are used for consumption data recording, signal processing, automated metering, theft detection, demand management or any combination thereof and the common display is able to simultaneously show analysis information and/or reading of the automated metering of at least two recipients.

2. The metering apparatus according to claim 1, further comprising a communication module connecting the processor to a remote server through a first wired or wireless communication that the remote server permits the recipient to make online payment and/or obtains the analysis information from the processor for further analysis and storage via the first wired or wireless communication.

3. The metering apparatus according to claim 2, wherein the consumable commodity is electricity and the first wired or wireless communication is a single power line communication.

4. The metering apparatus (100) according to claim 1, further comprising a multiplexer disposed in between the connection of the processor and the plurality of sensors prior to the signal processing unit that the multiplexer samples measurement of consumption data from each sensor to the processor at a predetermined duration.

5. The metering apparatus according to claim 1, wherein the display unit is a flat panel display or a text-based LCD.

6. The metering apparatus according to claim 1, wherein the consumable commodity is electricity and the theft detection relies on employment of Kirchoff s Law.

7. The metering apparatus according to claim 2, wherein the remote server is accessible through a second wired or wireless communication.

8. The metering apparatus according to claim 1, wherein the display unit is turned off when no input is received for a predetermined duration and is turned off upon receiving input from the user via the input system.

9. The metering apparatus according to claim 8, wherein the input system includes a sensing system emitting a signal beam that disruption to the signal beam prompts the display unit to be turned on.

10. The metering apparatus (100) according to claim 1, wherein the input system and the display unit are integrally fabricated as a single unit.

11. The metering apparatus according to claim 1, wherein the sensor is current and/or voltage transducer.

12. The metering apparatus according to claim 1, further comprising a privacy policy providing sets of configured criteria followed by the processor for presenting information on the display unit.

13. A method of simultaneously presenting multiple meter readings of a consumable commodity for multiple recipients located in a single building through a display unit (160), comprising the steps of:
measuring consumption data of the consumable commodity of each recipient using a sensor that the sensor measures consumption data without processing the consumption data;
gathering each measured consumption data from multiple recipients by a processor;
wherein each measured consumption data is processed via a signal processing unit before being acquired by the processor;
analyzing each measured consumption data of each recipient by the processor through instructions of one or more software applications to provide analysis information for each recipient;
recording the analysis information of each recipient in a storage device;
retrieving analysis information and/or measured consumption data of each recipient from the storage device and/or the processor; and
displaying the retrieved analysis information and/or measured consumption data of each recipient including the meter reading simultaneously in the display unit.

14. The method of claim 13, further comprising the step of:
turning off the display unit when no input is received by the processor via an input system and turning on the display unit upon receiving input from the input system.

15. The method of claim 13, wherein the instructions of one or more software applications are used for consumption data recording, signal processing, automated metering, theft detection, demand management or any combination thereof.

16. The method of claim 13, further comprising the steps of”
connecting the processor to a remote server via a communication module; and
announcing a message received from the server using the display unit.
